(19) United States
(12) Patent Application Publication
(10) Pub. No.: US 2002/0123253 A1
(43) Pub. Date: Sep. 5, 2002

(54) Low inductance connector

(76) Inventor: Forrest Sass, Pleasanton, CA (US)

Correspondence Address: FORREST SASS, 462 HAMILTON WAY, PLEASANTON, CA, 94566, US

(21) Appl. No.: 09/798,349

(22) Filed: Mar. 2, 2001

(51) Int. Cl. H05K 1/00

(52) U.S. Cl. 439/74

(57) ABSTRACT

An electrical connector for connecting a power source with a load wherein the connector has a pair of conducting members interconnecting the power source with the load and having insert apparatus inserted between the pair of conducting members and separated from inner surfaces thereof by dielectric material wherein the insert apparatus reduces the inductance of the connector by reducing a magnetic field between the pair of conducting members generated by current flow in the conductors and stores electrical energy within the connector.

### FIELD OF THE INVENTION

This invention relates to connector apparatus and in particular to a low inductance and energy storing connector.

### BACKGROUND OF THE INVENTION

Electrical connectors are oftentimes used to connect an electrical power source with a load such that electrical power may be applied by the source to the load. Typically, the electrical characteristics of such connectors may be represented as having one end of an inductance connected in series to one of a pair of terminals of the power source. The other end of the inductance is connected to one of a pair of terminals of the load with the other terminal of the power source connected to the other terminal of the load. The connector is completed by a capacitance connected in parallel with the terminals of the load.

In a basic configuration of such a connector, a pair of wires may be used to connect a battery to a load such as a resistor. A problem arises in that a long pair of wires increases both the inductance and capacitance of the connection. It was discovered that that the inductance of this type of connection could be reduced by bringing two round wires carrying equal and opposite current into very close proximity, such that the external opposing magnetic fields virtually cancelled each other. The result was a cable connection having a very low inductance. In order to improve the inductance of a wire connection, the pair of wires were twisted in close proximity about each other in various configurations to improve the inductance of the connection. This type of connection has been used in the past to connect the power source of a central telephone central office with subscriber telephone sets and is commonly found in many

In the connector industry, manufacturers have designed low inductance conductors for low level voltage and current and high frequency signal applications for many years. Typically, manufacture and distributor catalogs are filled with coax, BNC and other connector types for multi-MHz and GHz use. F-type of high frequency connectors can be purchased for terminating common 75-ohm TV cable. However, all of these connectors are designed for small-signal and low power connections and there are no high power connectors specifically designed with a low inductance for high frequency use.

The next generation of IC devices, particularly microprocessors, will require a vary low operating voltage in the order of one volt and in addition will have an internal clock frequency in excess of 1 GHz. This is in comparison to the 1980-vintage ICs that had an operating voltage of five volts and an internal clock frequency of about 8 MHz. In order to reduce power consumption of the new ICs, which can be 100W at full operation, sections of their circuitry may be turned off when not in use or the entire IC may enter a “sleep mode” when not in operation. However, these sections or the entire IC can turn back on in just one or more clock cycles thereby generating the IC current demand to ramp from 10A to 100A in just one nano-second.

A problem arises in that present connectors are a major contributor to circuit inductance in that the connector inductance results in the voltage across an IC to be momentarily diminished by any voltage drop across the connector which may result in a malfunction of the IC resulting in erroneous data output or computer lockup. Thus, there is a need in the art for a low inductance connector for interconnecting circuit boards and a power source to a load such as low operating voltage IC devices and for a connector having energy storage within the connector.

### SUMMARY OF THE INVENTION

It is an object of the invention to provide an electrical connector having conducting members and having an apparatus inserted in between the conducting members and separated from inner surfaces thereof by dielectric material for reducing the inductance of the connector by reducing a magnetic field between the pair of conducting members generated by current flow in the conductors and for storing electrical energy within the connector.

It is also an object of the invention to provide an electrical connector having a generally rectangular configured solid member formed of an electrical conducting material such as copper or copper alloy positioned between a pair of rectangular electrical conducting members and insulated by a dielectric material from bottom surfaces of the rectangular conducting members for reducing the magnetic field generated by opposite current flow in the rectangular electrical conducting members.

It is also an object of the invention to provide an electrical connector having a generally rectangular periphery configured window frame member formed of an electrical conducting material positioned between a pair of rectangular electrical conducting members and insulated by a dielectric material from bottom surfaces of the rectangular conducting members for reducing the magnetic field generated by opposite current flow in the rectangular electrical conducting members.

It is a further object of the invention to provide an electrical connector having a generally rectangular frame periphery member formed of an electrical conducting material covered with a dielectric material and mounting a plurality of multi-layer chip capacitors therein for storing electrical energy and having insulated openings therein enabling electrical connections between the capacitors and the rectangular conducting members and configured for enabling current flow around a periphery of the frame member in response to current flow in the rectangular conducting members to minimize inductance of the connector.

In a preferred embodiment of the invention, an electrical connector for interconnecting circuit boards and a power supply with an electrical load has a pair of generally rectangular configured conducting members formed of an electrical conducting material such as copper or copper alloy and having dimensions in the range of 5 mm×15 mm×0.125 mm to 150 mm×150 mm×12 mm for interconnecting the circuit boards and the power supply with the electrical load. The connector has a generally rectangular frame periphery member formed of electrically conducting material with dimensions in the range of 5 mm×8 mm×0.125 mm to 150 mm×100 mm×6 mm and having surfaces coated with a dielectric material wherein the periphery member mounts multi-layer chip capacitors positioned between the pair of rectangular conducting members. The periphery member has insulated openings therein enabling electrical connections between the capacitors and the pair of rectangular conducting members enabling the capacitors to store electrical energy in response to an electrical potential between the pair of conducting members. The frame member is configured for enabling current flow around a periphery of the frame member in response to current flow in the rectangular conducting members to minimize inductance of the connector. A housing formed of a non-conductive material covers the pair of rectangular conducting members and the frame periphery member to protect the electrical connector.

### BRIEF DESCRIPTION OF THE DRAWINGS

For a further understanding of the objects and advantages of the present invention, reference should be had to the following detailed description, taken in conjunction with the accompanying drawing figures, in which like parts are given like reference numerals and wherein:

FIG. 1 sets forth an electrical connector in accordance with principles of the invention for interconnecting coplanar circuit boards,

FIG. 2 illustrates another embodiment of the electrical connector apparatus set forth in FIG. 1 for interconnecting parallel circuit boards,

FIGS. 3 and 4 illustrates embodiments of the electrical connector set forth in FIGS. 1 and 2 for reducing the connector inductance,

FIG. 5 sets forth a construction of a capacitor insert in the electrical connectors of FIGS. 1 and 2 for storing electrical energy within the connectors,

FIG. 6 sets forth the electrical connectors of FIGS. 1 and 2 with inserts for reducing magnetic fields and for storing electrical energy within the connectors,

FIG. 7 sets forth the construction of an electrical chip capacitor for use in an insert in the connectors of FIGS. 1 and 2 for storing electrical energy within the connectors, and

FIG. 8 sets forth a complex insert for use with the connectors of FIGS. 1 and 2 to store electrical energy and to reduce inductance of the connectors.

### DETAILED DESCRIPTION OF THE INVENTION

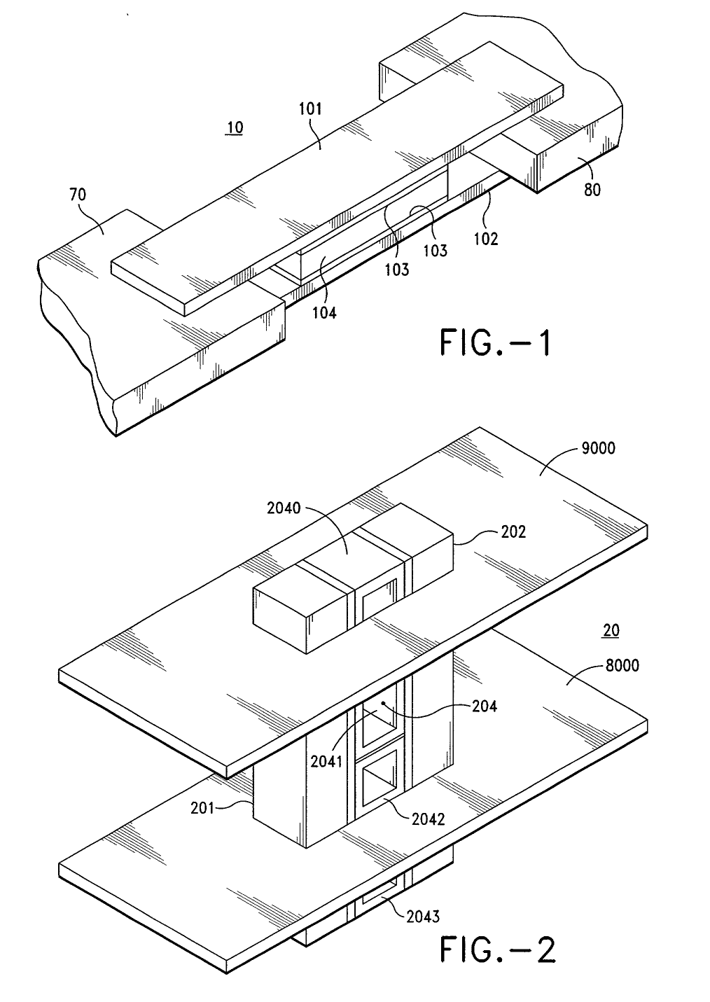

With particular reference to FIG. 1 of the drawing, there is shown an electrical connector 10 in accordance with principles of the invention for interconnecting a pair of circuit boards 70, 80 each positioned in a horizontal position with respect to the other. Circuit boards 70, 80 are comprised from a large group of various and different types of circuit boards, wherein various types of high speed electrical circuits located on the circuit boards require that the circuit boards be interconnected. In addition, a power source in one exemplary embodiment is positioned on one circuit board, for example, circuit board 70, and connected by electrical connector 10 with electrical circuitry positioned on circuit board 80 and acting as a load with respect to the power source positioned on circuit board 70.

Electrical connector 10, exhibits very low inductance and in one embodiment of the invention, stores electrical energy for use in interconnecting circuit boards or a power source with an electrical load. In general, although not limited thereto, it is used in an exemplary embodiment with IC devices that require a very low operating voltage on the order on one volt and which may require one hundred watts at full operation. The connector apparatus has a pair of conducting members 101 and 102 for interconnecting circuitry or power sources on circuit board 70 with circuitry or load on circuit board 80. Conducting members 101, 102 are each formed as a generally rectangular member of an electrical conducting material such as copper or copper alloy or other electrical conducting materials or combinations thereof. Typically, each conducting member 101 and 102 in various exemplary embodiments has dimensions, although not necessarily limited thereto, in the range of 5 mm×15 mm×0.125 mm to 150 mm×150 mm×12 mm. The conducting members 101 and 102 in one exemplary embodiment of the invention, the conducting members are spaced apart so that the bottom surfaces thereof are engageable with terminals or conductors located on the circuit boards 70 and 80.

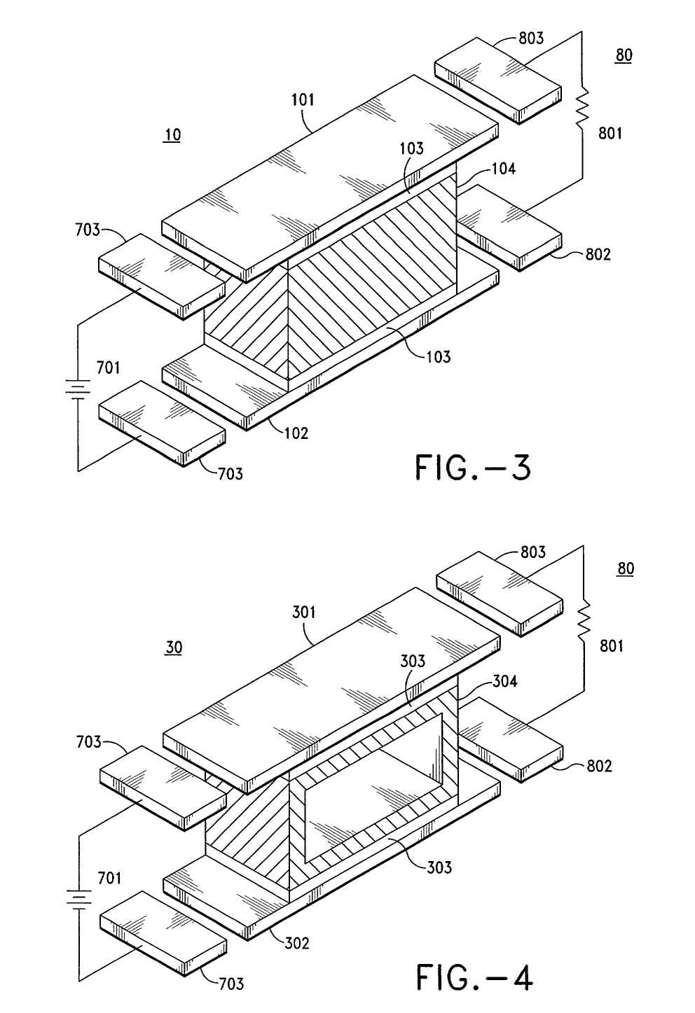

Electrical connector 10, FIG. 3, also has insert apparatus inserted between the pair of conducting members 101 and 102 and which is separated from inner surfaces of the conducting members 101 and 102 by dielectric material 103. Insert apparatus, herein represented as insert member 104, reduces magnetic fields generated by current flow in the conducting members 101 and 102. Typically, in various exemplary embodiments, the insert apparatus has dimensions in the range 5 mm×8 mm×0.125 mm to 150 mm×100 mm×6 mm. In one embodiment of the invention, the insert member 104 has a generally rectangular configured solid member formed of copper, copper alloy, brass, aluminum, titanium or similar electrical conducting material coated with a dielectric material 103. The dielectric material 103, depending on the insert material comes from anodized material, hard anodized material, Teflon, epoxy coating or similar type of material that will have a thickness dimension in the range of 0.0002 mm to 1 mm. Insert member 104 is positioned between the pair of rectangular electrical conducting members 101 and 102 and is insulated by the dielectric material 103 from the bottom surfaces of the rectangular conducting members 101 and 102. The electrically conducting material of insert member 104 reduces the magnetic fields generated by opposite current flow in the rectangular conducting members 101 and 102. In operation, current flows from one terminal 703 of a power source 701 and in one direction through conducting member 101, terminal 803, load 801, terminal 802 and in an opposite direction through conducting member 102, and terminal 702 back to the power source 701. The current flow through conducting members 101 and 102 generate magnetic fields that are reduced by solid insert member 104 thereby reducing the inductance and increasing the performance of connector 10.

In another embodiment of the invention, FIG. 4, connector 30 has insert apparatus consisting of a generally rectangular configured window frame member 304 formed of the electric conducting material coated with the insulating dielectric material 303 and positioned between the pair of rectangular electrical conducting members 301, 302. The dielectric material 303 insulates the window frame member 304 from bottom surfaces of the rectangular conducting members 301 and 302. In operation, current flow from power source 701 and terminals 702, 703 in opposite directions through conducting members 301 and 302 and terminals 802, 803 to load 801 generate magnetic fields about conducting members 301 and 302 which in turn produce a canceling current in the periphery of window frame member 304 thereby reducing the inductance of connector 30.

As set forth in FIG. 2 of the drawing, connector 20 in accordance with principles of the invention, may have an insert apparatus 204 consisting of a plurality of insert members 2040, 2041 and 2042 aligned and selectively positioned between a pair of generally rectangular conducting members 201 and 202. The insert apparatus 204 stores electrical energy within the connector 20 and reduces the inductance of connector 20 by reducing the magnetic field between the pair of conducting members 201 and 202. In addition to interconnecting two horizontal circuit boards 70 and 80 as is shown in FIG. 1, embodiments of the instant invention, FIG. 2, may also interconnect two parallel circuit boards 7000 and 8000. In either a horizontal or vertical connector application, the plurality of insert members 2040, 2041 and 2042 are formed of an electrical conducting material such as the aforementioned copper, copper alloy, brass, aluminum or titanium and coated with and separated from each other by an insulating dielectric material 2043 such as the aforementioned anodize, hard anodize, Teflon or epoxy. Connector 20 may also be used with a single multi-layered circuit board 8000 such that the rectangular conducting members 201 and 202 extend vertically upward from the surface of the circuit board 8000, but serve to interconnect electric circuits located on various surfaces of circuit board 8000 with the energy storage elements within 2040, 2041 and 2042. The insert members 2040, 2041 and 2042 are aligned along a common axis parallel to the conducting members 201, 202 and positioned between the conducting members 201, 202 with the upper and lower surfaces of insert members 2040, 2041 and 2042 insulated by the dielectric material 2043 from the conducting members 201 and 202.

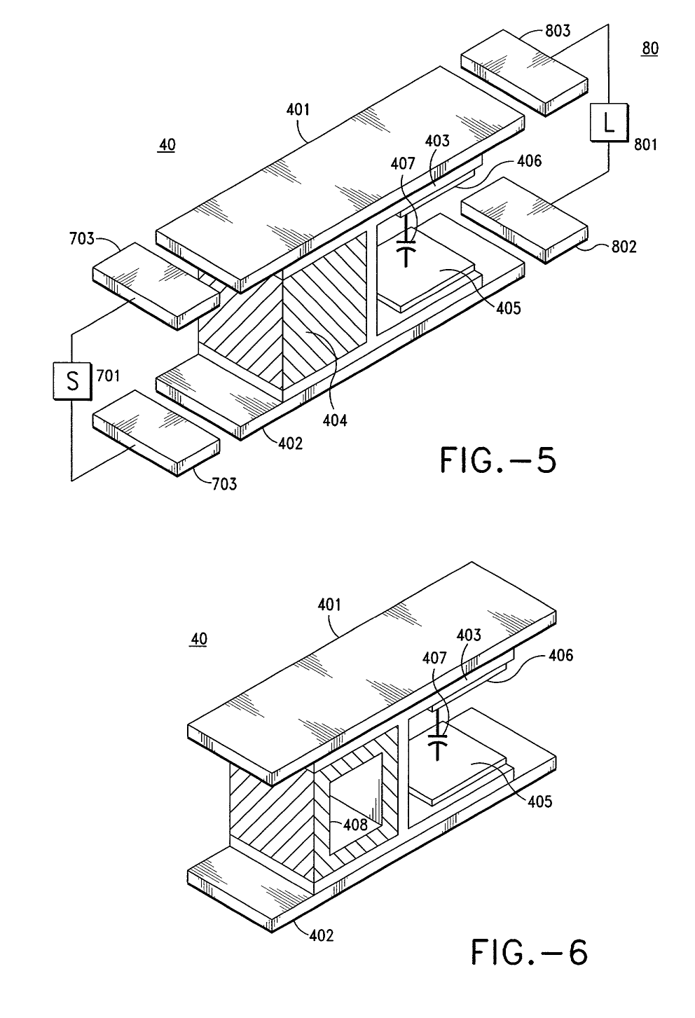

In a symbolic configuration, FIG. 5, connector 40 is shown as having insert members aligned and positioned between a pair of rectangular conducting members 401 and 402 interconnecting the terminals 703, 704 of a power source 701 with the terminals 802, 803 of an electrical load 803 and which serve to store electrical energy within connector 40 and to reduce inductance of connector 40. One of the insert members may be a solid rectangular electrical conducting member 404 insulated by dielectric material 403 from conducting members 401 and 402 and from the other insert member and which electrical conducting member 404 serves to reduce the inductance of connector 40. The other insert member is a capacitor circuit 407 having two terminals 406 and 405 connected through the insulating dielectric material 403 to the conducting members 401 and 402, respectively. In operation, current flow through conducting members 401 and 402 generate magnetic fields that are reduced by the solid electrical conducting member 404 to reduce the inductance and which current flow also charges capacitor 407 to store electrical energy within connector 40.

In another configuration, FIG. 6, one of the inserts of electrical connector 40 may be a generally rectangular configured periphery window frame member 408 formed of electric conducting material and positioned between the pair of rectangular electrical conducting members 402, 403 and coated with the insulating dielectric material 403. The reduction of current induced by the magnetic fields generated by current in the conducting members 401 and 402 in the periphery of window frame member 408 reduces the inductance of electrical connector 40 while the capacitor 407 is charged to store electric energy within the connector 40.

The electrical connectors of the present embodiments, such as electrical connector 40, use an insert or multiple inserts mounting multi-layer chip capacitors 507, FIG. 7, positioned between the pair of rectangular conducting members 401 and 402. The multi-layer chip capacitors 507 are electrically connected to the pair of rectangular conducting members 401 and 402 for storing and delivering high pulse energy to the high speed electrical load, FIG. 5, connected between the rectangular conducting members 401 and 402. Typically, the capacitor chips 5070 have terminals 5071 that are electrically insulated from an insert member and electrically connected to the connector conducting members 401 and 404 so that current flowing in the conducting members 401 and 402 will charge capacitors 5070 and allow them to store electrical energy within connector 40.

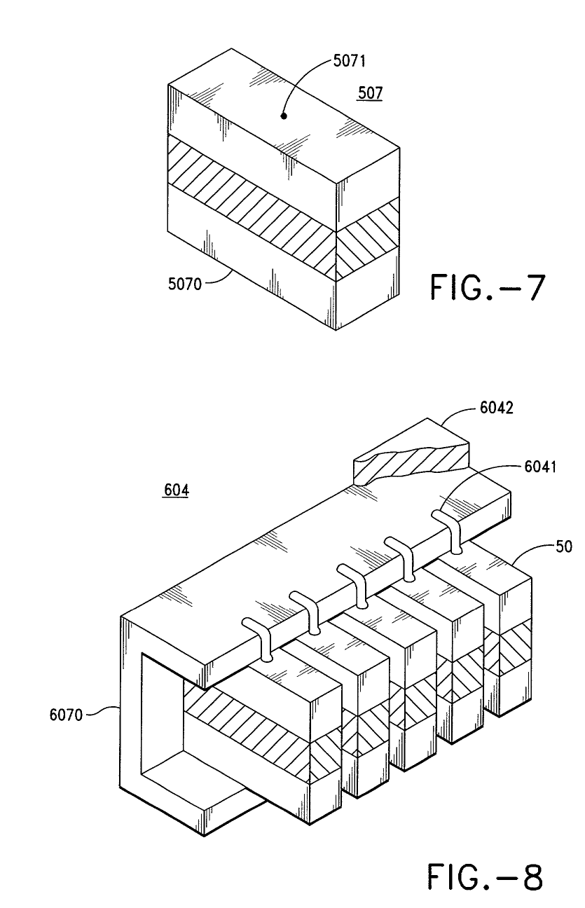

The insert member for an electrical connector 40 may be a generally rectangular frame periphery member 604, FIG. 8, for holding multiple capacitors 507 that are aligned and positioned along a center longitudinal axis of member 604 to store electrical energy within the connector 40. Insert member 604 has, although not limited thereto, a general rectangular configuration 6040 and is formed of copper, or other ones of the aforementioned conducting materials and has openings 6041 formed in opposite surfaces thereof enabling electrical connections between capacitors 507 and the connector conducting members 401 and 402, FIG. 5. Dielectric insulating material 6042, FIG. 8, is applied to all surfaces of periphery member 604 and is formed to have to openings therein corresponding with the openings of periphery member 604. The openings 6041 of periphery member 604 are insulated by insulating material 6042 and enable electrical connections between the capacitors 507 and the connector conducting members 401 and 402, FIG. 5. In operation, current flowing in the connector conducting members 401, 402 generate magnetic fields enabling current flow around a periphery of the frame member 6040 to minimize inductance of the connector 40 and allows capacitors 507 to charge and store electrical energy within connector 40. A housing formed of a non-conductive material may be used to cover a part of the pair of the connector conducting members and the insert member 604 energy storing and inductance reducing apparatus to protect the connector.

It is obvious from the foregoing that the facility, economy and performance of electrical connectors is improved by connector apparatus arranged to minimize inductance and to store electrical energy in interconnecting circuit boards and power sources with high speed and low power electrical loads. While the foregoing detailed description is described in embodiments of electrical connectors in accordance with principles of the invention, it is to be understood that the above description is illustrative only and is not limiting of the disclosed invention. Particularly other configurations of electrical connector insert devices for reducing inductance of the connector and for storing electrical energy within the connector are within the scope and sprit of this invention. Thus, the invention is to be limited only by the claims set forth below.

What is claimed is:

1. An electrical connector comprising
a pair of conducting members for interconnecting circuit boards and a power source with a load, and
apparatus inserted between the pair of conducting members and separated from inner surfaces thereof by dielectric material for storing electrical energy within the connector and for reducing the inductance of the connector by reducing a magnetic field between the pair of conducting members generated by current flow in the conductors.

2. The electrical connector set forth in claim 1 wherein the pair of conducting members each comprise
a generally rectangular member formed of an electrical conducting material.

3. The electrical connector set forth in claim 2 wherein the electrical storing and magnetic field reducing apparatus comprises
insert apparatus selectively positioned between the pair of rectangular conducting members and configured for storing electrical energy within the connector and for reducing the inductance of the connector by reducing a magnetic field between the pair of rectangular conducting members that is generated by a flow of opposite electrical current in the pair of rectangular conducting members.

4. The electrical connector set forth in claim 3 wherein the insert apparatus comprises
a generally rectangular configured solid member positioned between the pair of rectangular conducting members and insulated by a dielectric material from bottom surfaces of the rectangular conducting members and formed of an electrically conducting material for reducing the magnetic field generated by opposite current flow in the rectangular conducting members.

5. The electrical connector set forth in claim 3 wherein the insert apparatus comprises
a generally rectangular configured window frame member positioned between the pair of rectangular conducting members and insulated by a dielectric material from bottom surfaces of the rectangular conducting members and formed of an electrically conducting material for reducing the magnetic field generated by opposite current flow in the rectangular conducting members.

6. The electrical connector set forth in claim 3 wherein the insert apparatus comprises
a plurality of insert members aligned and selectively positioned between the pair of rectangular conducting members for storing electrical energy within the connector and for reducing the inductance of the connector by reducing the magnetic field between the pair of rectangular conducting members.

7. The electrical connector set forth in claim 6 wherein ones of the insert members comprises
a generally rectangular configured solid member of copper and copper alloy positioned between the pair of rectangular conducting members and insulated therefrom by a dielectric material from bottom surfaces of the rectangular conducting members for reducing the magnetic field generated by opposite current flow in the rectangular conducting members.

8. The electrical connector set forth in claim 6 wherein ones of the insert members comprises
multi-layer chip capacitors positioned between the pair of rectangular conducting members and electrically connected thereto for storing and delivering high pulse energy to the load connected between the rectangular conducting members.

9. The electrical connector set forth in claim 8 wherein ones of the insert members comprises
a capacitor holding member positioned between the pair of rectangular conducting members for mounting a plurality of the multi-layer chip capacitors therein and having openings therein enabling electrical connections between the capacitors and the rectangular conducting members.

10. The electrical connector set forth in claim 9 wherein the capacitor holding member comprises
a generally rectangular frame periphery member for holding the capacitors therein to store electrical energy and formed of copper with an insulating material applied to all surfaces and having the openings formed in opposite surfaces thereof enabling the electrical connections between the capacitors and the rectangular conducting members and configured for enabling current flow around a periphery of the frame member to minimize inductance of the connector.

11. The electrical connector set forth in claim 9 further comprising
an housing covering a part of the pair of rectangular conducting members and the energy storing and inductance reducing apparatus formed of a non-conductive material for protecting the electrical connector.

12. An electrical connector for interconnecting circuit boards and for connecting a power source with a load wherein the electrical connector comprises
a pair of generally rectangular configured conducting members for interconnecting the circuit boards and the power source with the load, and
an insert of a generally rectangular configured solid member positioned between the pair of rectangular conducting members and insulated by a dielectric material from bottom surfaces of the rectangular conducting members and formed of an electrically conducting material for reducing a magnetic field generated by opposite current flow in the rectangular conducting members.

13. An electrical connector for connecting a power source with a load wherein the electrical connector comprises
a pair of generally rectangular configured conducting members for interconnecting the power source with the load, and
a generally rectangular frame periphery member positioned between the pair of rectangular conducting members and insulated by a dielectric material from bottom surfaces of the rectangular conducting members and formed of an electrically conducting material for reducing a magnetic field generated by opposite current flow in the rectangular conducting members by reducing current flow around a periphery of the frame member to minimize inductance of the connector.

14. An electrical connector for connecting a power source with a load wherein the electrical connector comprises
a pair of generally rectangular configured conducting members for interconnecting the power source with the load, and
an insert member positioned between the pair of rectangular conducting members for storing electrical energy within the connector and for reducing an inductance of the connector by reducing a magnetic field between the pair of rectangular conducting members.

15. The electrical connector set forth in claim 14 wherein the insert member comprises
a generally rectangular frame periphery member mounting a plurality of multi-layer chip capacitors therein for storing electrical energy and having openings therein enabling electrical connections between the capacitors and the rectangular conducting members and configured for enabling current flow around a periphery of the frame member in response to current flow in the rectangular conducting members to minimize inductance of the connector.

16. An electrical connector for connecting a power source with a load wherein the electrical connector comprises
a pair of generally rectangular configured conducting members for interconnecting the power source with the load, and
a generally rectangular frame periphery member positioned between the pair of rectangular conducting members mounting a plurality of multi-layer chip capacitors and having openings therein enabling electrical connections between the capacitors and the pair of rectangular conducting members for storing electrical energy in response to an electrical potential between the pair of conducting members and which frame member is configured for enabling current flow around a periphery of the frame member in response to current flow in the rectangular conducting members to minimize inductance of the connector.

17. The electrical conductor set forth in claim 16 wherein the rectangular frame periphery member is formed of copper with an insulating material applied to all surfaces and having the openings formed in opposite surfaces thereof enabling the electrical connections between the capacitors and the rectangular conducting members.

18. An electrical connector for connecting circuit boards comprising
a pair of generally rectangular configured conducting members for interconnecting the circuit boards,
a generally rectangular frame periphery member mounting a plurality of multi-layer chip capacitors positioned between the pair of rectangular conducting members and having openings therein enabling electrical connections between the capacitors and the pair of rectangular conducting members for storing electrical energy in response to an electrical potential between the pair of conducting members and which frame member is configured for enabling current flow around a periphery of the frame member in response to current flow in the rectangular conducting members to minimize inductance of the connector, and
a housing covering the pair of rectangular conducting members and the frame periphery member wherein the housing is formed of a non-conductive material for protecting the electrical connector.

19. An insert for use with an electrical connector comprising
an insulated frame periphery member formed of electrical conducting material for mounting a plurality of multi-layer chip capacitors positioned between a pair of conducting members of the electrical connector and having insulated openings in surfaces thereof enabling electrical connections between the capacitors and the pair of conducting members for storing electrical energy in response to an electrical potential between the pair of conducting members and which frame member is configured for enabling current flow around a periphery of the frame member in response to current flow in the conducting members to minimize inductance of the connector.
